(19) United States
(12) Patent Application Publication
(10) Pub. No.: US 2009/0058696 A1
(43) Pub. Date: Mar. 5, 2009

(54) METHOD AND APPARATUS FOR REAL-TIME TIME-DOMAIN INTEGRATION OR DIFFERENTIATION OF VIBRATION SIGNALS

(75) Inventor: Joseph C. Baldwin, Knoxville, TN (US)

Correspondence Address: LUEDEKA, NEELY & GRAHAM, P.C., P O BOX 1871, KNOXVILLE, TN, 37901, US

(73) Assignee: CSI TECHNOLOGY, INC., Wilmington, DE (US)

(21) Appl. No.: 12/205,405

(22) Filed: Sep. 5, 2008

Related U.S. Application Data
(60) Provisional application No. 60/970,035, filed on Sep. 5, 2007.

(51) Int. Cl. H03M 1/00

(52) U.S. Cl. 341/110

(57) ABSTRACT

A vibration data collection system performs an integration or differentiation process on incoming digitized vibration data in real time. The system uses a digital Infinite Impulse Response (IIR) filter running at the input data rate to provide the integration or differentiation function. With this approach, the system reduces hardware complexity and data storage requirements. Also, the system provides the ability to directly integrate or differentiate stored time waveforms without resorting to FFT processing methods.

This application claims priority to U.S. provisional application Ser. No. 60/970,035 filed Sep. 5, 2007, titled “Method and Apparatus for Real-Time Time-Domain Integration or Differentiation of Vibration Signals,” the entire contents of which are incorporated herein by reference.

### FIELD

This invention relates to the field of vibration monitoring systems for use in detecting machine fault conditions and analyzing machine performance. More particularly, this invention relates to a system for performing real-time digital integration or differentiation of time domain signals indicative of vibration produced by a machine.

### BACKGROUND

Conversion from one type of vibration-related signal (such as acceleration) to another vibration-related signal (such as velocity or displacement) is a common requirement for vibration monitoring systems. A typical example is the conversion from acceleration to velocity by integration of the acceleration signal. Similarly, the opposite conversion can be performed by differentiating a velocity signal. In the past, these conversions have been done using analog hardware filters. Such conversions have also been done after data collection, using software that performs a Fast Fourier Transform (FFT) and operates on the transformed data in the frequency domain.

An ideal hardware integrator is shown in FIG. 4. This circuit directly converts an acceleration (or velocity) signal to velocity (or displacement) with a conversion factor proportional to 1/R1×C2. Unfortunately, this circuit has not suitable in practice due to the high DC gain. The circuit quickly saturates due to offset currents and voltages of the operational amplifier. A more refined approach is shown in FIG. 5, where the addition of R2 and C1 limit the low-frequency response of the operational amplifier to prevent saturation. The appropriate selection of R1 and C2 gives a direct conversion between units, (e.g. 61.45/f for conversion of acceleration to velocity). This approach converts the signal directly, prior to data acquisition, so that no additional data processing is required. However, it offers no flexibility in changing the conversion factors and is subject to variability in hardware component values. Also, it consumes large amounts of circuit board real estate due to the physically large components required for low-frequency operation.

Another prior art approach to the conversion is to digitize the vibration signal using an analog-to-digital converter (ADC), transform to the frequency domain using FFT methods, and apply integration or differentiation on the frequency spectrum. This process is depicted in FIG. 6. Disadvantages of this approach include the lack of ability to do the conversion process continuously in real-time and the system complexity required to perform the FFT. Also, creation of an integrated time waveform requires extensive data processing (i.e., forward and inverse FFT computations). Finally, the FFT method assumes the signal is stationary which may not be true for dynamic signal conditions and could lead to errors in the re-creation of the time domain signal.

What is needed, therefore, is a conversion process that reduces hardware complexity, reduces data storage requirements, and provides for direct integration or differentiation of time-domain vibration waveforms without resorting to FFT methods.

### SUMMARY

The above and other needs are met by a vibration data collection system that performs the integration or differentiation process on incoming digitized vibration data in real time. The system uses digital Infinite Impulse Response (IIR) filters running at the input data rate to provide the integration or differentiation function. With this approach, the system reduces hardware complexity and data storage requirements. Also, the system provides the ability to directly integrate or differentiate stored time waveforms without resorting to FFT processing methods.

In one preferred embodiment, the invention provides a signal conversion apparatus for use in a machine vibration monitoring system. The signal conversion apparatus of this embodiment comprises an ADC circuit and a digital IIR filter. The ADC circuit receives a time-domain analog signal that is indicative of a vibration level of a machine, and converts the time-domain analog signal into a first time-domain digital signal. The digital IIR filter receives the first time-domain digital signal and performs a mathematical operation on the first time-domain digital signal to generate a second time-domain digital signal substantially in real time, where the second time-domain digital signal is indicative of the vibration level of the machine. The mathematical operation may be an integration operation or a differentiation operation.

In some embodiments, the ADC circuit converts the time-domain analog signal into a plurality of input data values of the first time-domain digital signal during a first period of time corresponding to a plurality of ADC clock cycles. The digital IIR filter generates a plurality of output data values of the second time-domain digital signal during the first period of time.

In some embodiments, the digital IIR filter performs the mathematical operation on the plurality of input data values of the first time-domain digital signal to generate the plurality of output data values of the second time-domain digital signal according to:

yₙ=A·xₙ+B·xₙ₋₂+C·yₙ₋₁+D·Yₙ₋₂,

where

yₙ is an nth output data value of the second time-domain digital signal,

yₙ₋₁ is an output data value of the second time-domain digital signal prior to output data value yₙ,

yₙ₋₂ is an output data value of the second time-domain digital signal prior to yₙ₋₁,

xₙ is an nth input data value of the first time-domain digital signal,

xₙ₋₁ is an input data value of the first time-domain digital signal prior to xₙ,

xₙ₋₂ is an input data value of the first time-domain digital signal prior to xₙ₋₁, and A, B, C and D are constants.

In some embodiments, the mathematical operation is an integration operation, the first time-domain digital signal is an acceleration signal and the second time-domain digital signal is a velocity signal. In some embodiments, the mathematical operation is an integration operation, the first time-domain digital signal is velocity signal and the second time-domain digital signal is a displacement signal. In some embodiments, the mathematical operation is a differentiation operation, the first time-domain digital signal is a velocity signal and the second time-domain digital signal is an acceleration signal. In some embodiments, the mathematical operation is a differentiation operation, the first time-domain digital signal is a displacement signal and the second time-domain digital signal is a velocity signal.

In another aspect, the invention provides a real-time method for converting vibration-related signals acquired by a machine vibration monitoring system. The method includes:
(a) receiving a time-domain analog signal that is indicative of a vibration level of a machine;
(b) converting the time-domain analog signal into a first time-domain digital signal;
(c) performing a mathematical operation on the first time-domain digital signal to generate a second time-domain digital signal substantially in real time, where the second time-domain digital signal is indicative of the vibration level of the machine, and where the mathematical operation is either an integration operation or a differentiation operation.

In yet another aspect, the invention provides a method for converting previously-stored vibration-related signals that were acquired by a machine vibration monitoring system. The method includes:
(a) receiving a time-domain analog signal that is indicative of a vibration level of a machine;
(b) converting the time-domain analog signal into a first time-domain digital signal;
(c) storing the first time-domain digital signal in a data storage device;
(d) accessing the first time-domain digital signal from the data storage device;
(e) performing a mathematical operation on the first time-domain digital signal to generate a second time-domain digital signal, wherein the second time-domain digital signal is indicative of the vibration level of the machine, and wherein the mathematical operation is selected from the group consisting of an integration operation and a differentiation operation.

### BRIEF DESCRIPTION OF THE DRAWINGS

Further advantages of the invention are apparent by reference to the detailed description in conjunction with the figures, wherein elements are not to scale so as to more clearly show the details, wherein like reference numbers indicate like elements throughout the several views, and wherein:

FIG. 1 depicts an ideal real-time integrator according to an embodiment of the invention;

FIG. 2 depicts a band-limited real-time integrator according to an embodiment of the invention;

FIG. 3 depicts a frequency response curve for an IIR integrator and a band-limited analog integrator;

FIG. 4 depicts an ideal hardware integrator;

FIG. 5 depicts an band-limited hardware integrator; and

FIG. 6 depicts an FFT vibration data processing scheme.

### DETAILED DESCRIPTION

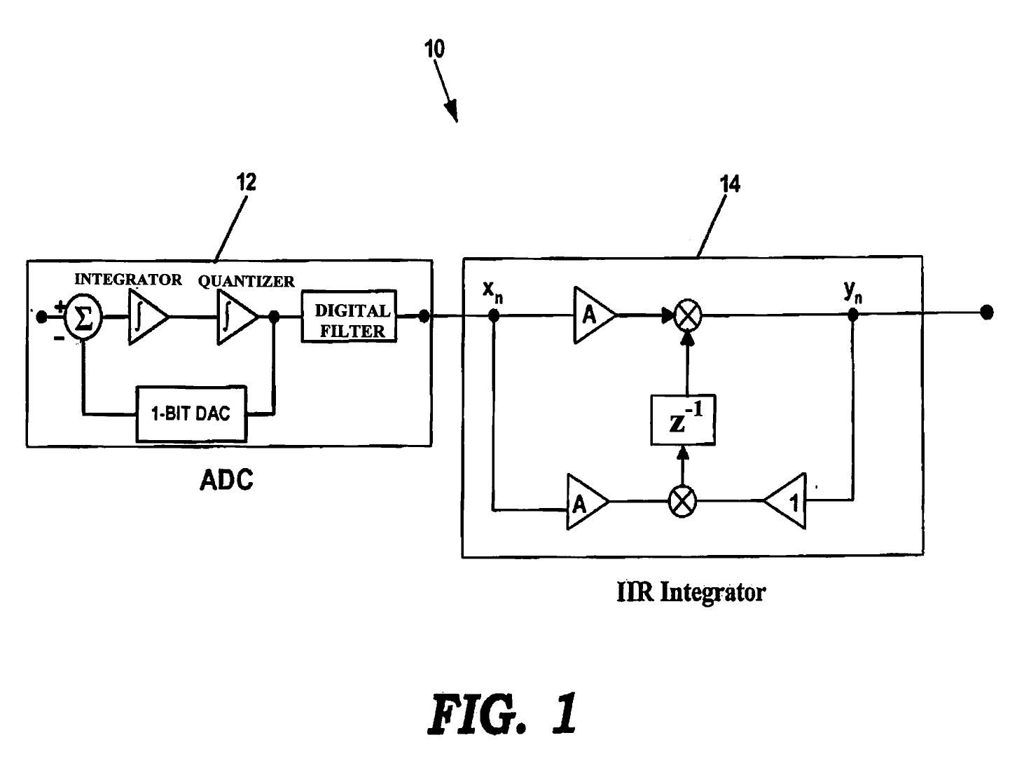

The basic structure for an ideal real-time integrator system IO is depicted in FIG. 1. The ideal system 10 includes an analog-to-digital converter (ADC) 12 and an ideal integrator 14. The ideal integrator 14 may be implemented using a difference equation which requires only one multiply operation, two addition operations and one storage location per ADC clock cycle. This difference equation is expressed as:

yₙ:yₙ₋₁+A(xₙ+xₙ₋₁) (1)

where yₙ is the current output value, xₙ is the current input value, yₙ₋ᵢ is the previous output value and xₙ₋₁ is the previous input value. In equation (1), A is a constant derived from the conversion factor.

The difference equation (1) may be derived by taking the ideal integrator transfer function in the s-domain (complex frequency domain) according to:

$$\begin{matrix}H ( s ) := \frac{A}{s} \\ where & ( 2 ) \\ s := 2 \cdot \frac{( 1 - {Z}^{- 1} )}{dt \cdot ( 1 + {Z}^{- 1} )} . & ( 3 )\end{matrix}$$

Applying the bilinear transform results in the following relationship:

$$X ( Z ) \cdot X ( 1 + {Z}^{- 1} ) := \frac{Y ( Z ) \cdot ( 1 - {Z}^{- 1} )}{A} \qquad ( 4 )$$

Rearranging terms and applying the inverse Z transform results in the time domain difference equation (1).

The difference equation (1) may be implemented in a digital signal processor (DSP) or general purpose processor as a first order IIR filter. The problems inherent to the ideal integrator as described above are also found in the digital implementation. The infinite gain at DC amplifies low-frequency noise and offsets, and the constant of integration remains in the output sequence. Using the analog implementation as a guide, the digital equivalent of the band-limited integrator can be created using the method described above. The resultant difference equation is given by:

yₙ=A·xₙ+B·xₙ₋₂+C·yₙ₋₁+D·yₙ₋₂ (5)

where xₙ₋₂ is the input value prior to xₙ₋₁, yₙ₋₂ is the output value prior to yₙ₋₁, and A, B, C and D are constants determined by the desired high-pass frequency and integrator conversion factor. This filter requires four multiply operations, three addition operations and two storage locations per ADC clock cycle which can be efficiently implemented in most processors.

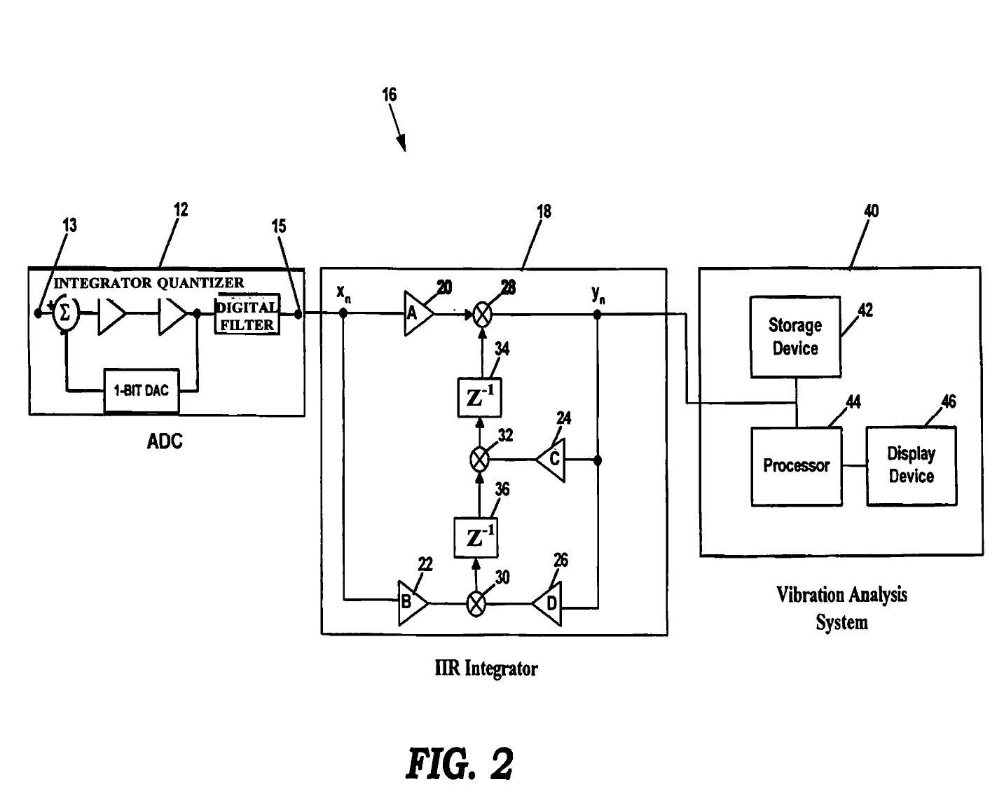

FIG. 2 depicts an embodiment of a signal conversion apparatus 16 which implements the filter of equation (5). This embodiment of the apparatus 16 includes an ADC 12 and an infinite impulse response (IIR) filter module 18. A time-domain analog vibration-related signal, such as an accelerometer signal measured at some point of interest on a machine, is applied to an input 13 of the ADC. The time-domain analog vibration-related signal could also be a velocity signal or a displacement signal. The ADC 12 converts the analog vibration-related signal into a first time-domain digital signal, xₙ, at the output 15 of the ADC 12. The signal, xₙ, is provided to the filter module 18 which generates a second time-domain digital signal, yₙ, at its output according to the filter of equation (5).

As shown in FIG. 2, a preferred embodiment of the filter module 18 includes a multiply operation 20 for implementing the A·xₙ operation, a multiply operation 22 for implementing the B·xₙ₋₂ operation, a multiply operation 24 for implementing the C·yₙ₋₁ operation, and a multiply operation 26 for implementing the D·yₙ₋₂ operation. The filter module 18 also includes three addition operations 28, 30 and 32, and two unit delay storage operators 34 and 36.

The output of the filter module 18 is provided to a vibration analysis system 40 which preferably comprises a computer processor 44, digital storage device 42 and display device 46. The vibration analysis system 40 may be implemented in a handheld vibration analyzer, in a notebook computer, a desk top computer or server. The vibration analysis system 40 receives the second time-domain digital signal, yₙ, which may be an acceleration signal, velocity signal or displacement signal, and processes the signal, yₙ, to provide machine vibration data in a format that is useful to a machine vibration analyst. The processed machine vibration data may be displayed on the display device 46 for observation by the vibration analyst or stored on the storage device 42 for subsequent processing or display.

It will be appreciated that the filter module 18 may be implemented in a digital signal processor, general purpose processor, or implemented entirely in hardware as in an FPGA or ASIC that is separate from the processor 44 of the vibration analysis system 40, or the filter module 18 may be implemented in the processor 44.

In alternative embodiments of the invention, the first time-domain digital signal, Xₙ, at the output of the ADC 12 is stored in a digital storage device, such as the device 42, as the data is sampled. The stored signal, xₙ, may subsequently be processed by the filter module 18 to generate the second time-domain digital signal, yₙ. In this manner, the system 16 provides the ability to directly integrate or differentiate stored time-domain waveforms without resorting to FFT processing methods.

As will be appreciated by those skilled in the art, the topology for a differentiator implementation of the filter 18 is substantially identical to that depicted in FIG. 2, and only requires different values of the coefficients A, B, C and D.

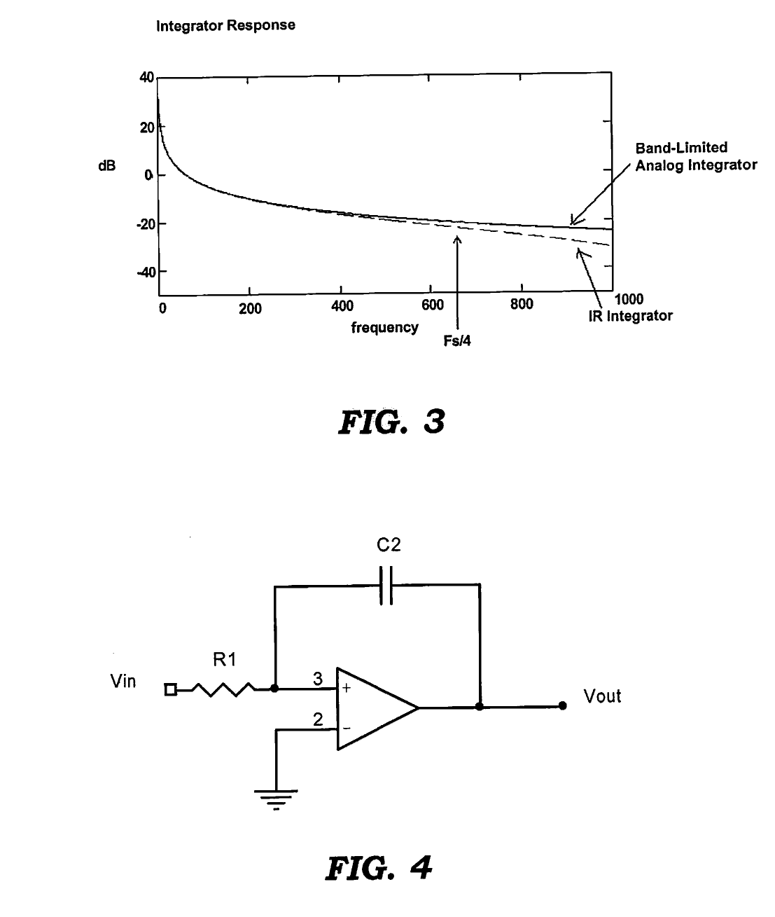

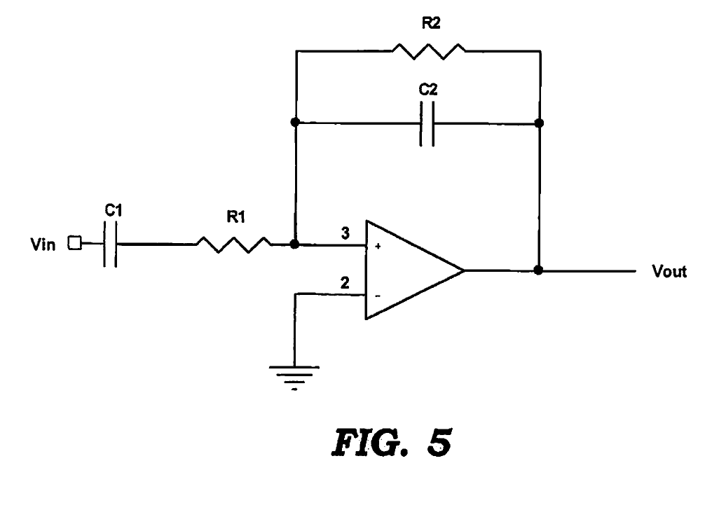

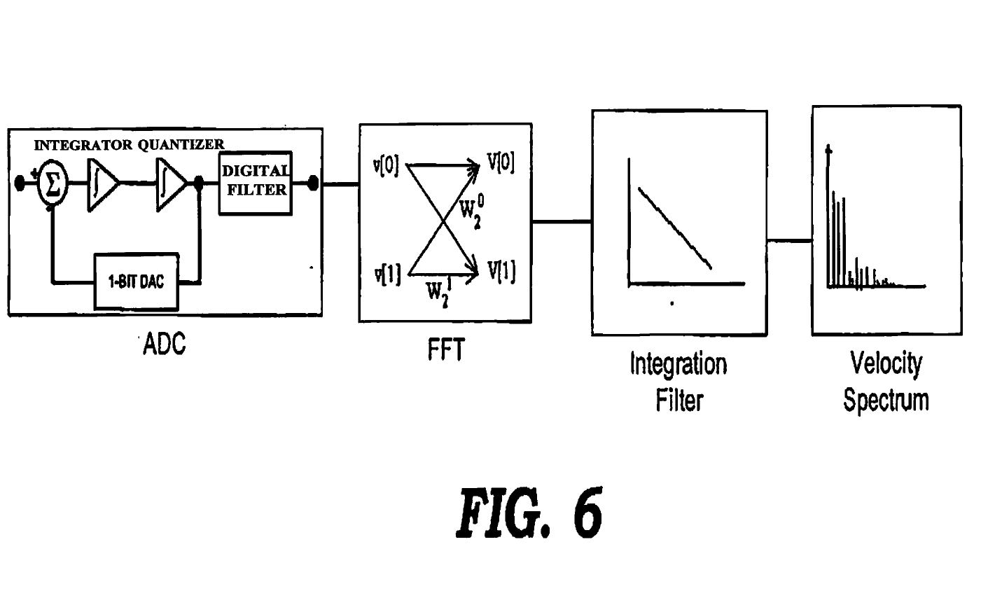

For optimum results, the sampling data rate should be at least twice the Nyquist frequency (Fs/2) due the frequency warping of the bilinear transform process. As shown in FIG. 3, the IIR implementation begins to deviate from the ideal case at about Fs/4. In practice, this is not a severe limitation, as over-sampling is often required for other related vibration analysis functions.

In summary, by implementing the integration function in the digital data stream, vibration units are efficiently transformed in real time with very little data storage and with complete flexibility in the conversion type.

The foregoing description of preferred embodiments for this invention have been presented for purposes of illustration and description. They are not intended to be exhaustive or to limit the invention to the precise form disclosed. Obvious modifications or variations are possible in light of the above teachings. The embodiments are chosen and described in an effort to provide the best illustrations of the principles of the invention and its practical application, and to thereby enable one of ordinary skill in the art to utilize the invention in various embodiments and with various modifications as are suited to the particular use contemplated. All such modifications and variations are within the scope of the invention as determined by the appended claims when interpreted in accordance with the breadth to which they are fairly, legally, and equitably entitled.

What is claimed is:

1. A signal conversion apparatus for use in a machine vibration monitoring system, the signal conversion apparatus comprising:
an analog-to-digital conversion (ADC) circuit for receiving a time-domain analog signal that is indicative of a vibration level of a machine, and for converting the time-domain analog signal into a first time-domain digital signal; and
a digital infinite impulse response filter for receiving the first time-domain digital signal and performing a mathematical operation on the first time-domain digital signal to generate a second time-domain digital signal substantially in real time, wherein the second time-domain digital signal is indicative of the vibration level of the machine, and wherein the mathematical operation is selected from the group consisting of an integration operation and a differentiation operation.

2. The signal conversion apparatus of claim 1 wherein
the analog-to-digital conversion circuit converts the time-domain analog signal into a plurality of first input data values of the first time-domain digital signal during a first period of time corresponding to a plurality of ADC clock cycles; and
the digital infinite impulse response filter generates a plurality of first output data values of the second time-domain digital signal during the first period of time.

3. The signal conversion apparatus of claim 1 wherein:
the analog-to-digital conversion circuit generates a plurality of input data values of the first time-domain digital signal; and
the digital infinite impulse response filter performs the mathematical operation on the plurality of input data values of the first time-domain digital signal to generate a plurality of output data values of the second time-domain digital signal according to:
yₙ=A·xₙ+B·xₙ₋₂+C·yₙ₋₁+D·yₙ₋₂
where
yₙ is an nth output data value of the second time-domain digital signal,
yₙ₋₁ is an output data value of the second time-domain digital signal prior to output data value yₙ,
yₙ₋₂ is an output data value of the second time-domain digital signal prior to yₙ₋₁,
xₙ is an nth input data value of the first time-domain digital signal,
xₙ₋₁ is an input data value of the first time-domain digital signal prior to xₙ,
xₙ₋₂ is an input data value of the first time-domain digital signal prior to xₙ₋₁, and A, B, C and D are constants.

4. The signal conversion apparatus of claim 1 wherein the mathematical operation is an integration operation, the first time-domain digital signal is an acceleration signal and the second time-domain digital signal is a velocity signal.

5. The signal conversion apparatus of claim 1 wherein the mathematical operation is an integration operation, the first time-domain digital signal is velocity signal and the second time-domain digital signal is a displacement signal.

6. The signal conversion apparatus of claim 1 wherein the mathematical operation is a differentiation operation, the first time-domain digital signal is a velocity signal and the second time-domain digital signal is an acceleration signal.

7. The signal conversion apparatus of claim 1 wherein the mathematical operation is a differentiation operation, the first time-domain digital signal is a displacement signal and the second time-domain digital signal is a velocity signal.

8. A signal conversion apparatus for use in a machine vibration monitoring system, the signal conversion apparatus comprising:
an analog-to-digital conversion (ADC) circuit for receiving a time-domain analog signal that is indicative of a vibration level of a machine and for converting the time-domain analog signal into a first time-domain digital signal, wherein the analog-to-digital conversion circuit generates a plurality of input data values of the first time-domain digital signal during a corresponding plurality of ADC clock cycles; and
a digital infinite impulse response filter for receiving the plurality of input data values of the first time-domain digital signal and generating a plurality of output data values of a second time-domain digital signal during the plurality of ADC clock cycles according to:
yₙ=A·xₙ+B·xₙ₋₂+C·yₙ₋₁+D·yₙ₋₂,
where
yₙ is an nth output data value of the second time-domain digital signal,
yₙ₋₁ is an output data value of the second time-domain digital signal prior to yₙ,
yₙ₋₂ is an output data value of the second time-domain digital signal prior to yₙ₋₁,
xₙ is an nth input data value of the first time-domain digital signal,
xₙ₋₁ is an input data value of the first time-domain digital signal prior to xₙ,
xₙ₋₂ is an input data value of the first time-domain digital signal prior to xₙ₋₁, and A, B, C and D are constants.

9. A method for converting vibration-related signals acquired by a machine vibration monitoring system, the method comprising:
(a) receiving a time-domain analog signal that is indicative of a vibration level of a machine;
(b) converting the time-domain analog signal into a first time-domain digital signal;
(c) performing a mathematical operation on the first time-domain digital signal to generate a second time-domain digital signal substantially in real time, wherein the second time-domain digital signal is indicative of the vibration level of the machine, and wherein the mathematical operation is selected from the group consisting of an integration operation and a differentiation operation.

10. The method of claim 9 wherein:
step (b) comprises converting the time-domain analog signal into the first time-domain digital signal during a first period of time corresponding to plurality of data clock cycles, where the first time-domain digital signal comprises a plurality of input data values; and
step (c) comprises generating a plurality of output data values of the second time-domain digital signal during the first period of time corresponding to the plurality of data clock cycles according to:
yₙ=A·xₙ+B·xₙ₋₂+C·yₙ₋₁+D·yₙ₋₂,
where
yₙ is an nth output data value of the second time-domain digital signal,
yₙ₋₁ is an output data value of the second time-domain digital signal prior to yₙ,
yₙ₋₂ is an output data value of the second time-domain digital signal prior to yₙ₋₁,
xₙ is an nth input data value of the first time-domain digital signal,
xₙ₋₁ is an input data value of the first time-domain digital signal prior to xₙ,
xₙ₋₂ is an input data value of the first time-domain digital signal prior to xₙ₋₁, and A, B, C and D are constants.

11. The method of claim 9 wherein the mathematical operation is an integration operation, the first time-domain digital signal is an acceleration signal, and the second time-domain digital signal is a velocity signal.

12. The method of claim 9 wherein the mathematical operation is an integration operation, the first time-domain digital signal is a velocity signal, and the second time-domain digital signal is a displacement signal.

13. The method of claim 9 wherein the mathematical operation is a differentiation operation, the first time-domain digital signal is an velocity signal, and the second time-domain digital signal is an acceleration signal.

14. The method of claim 9 wherein the mathematical operation is a differentiation operation, the first time-domain digital signal is a displacement signal, and the second time-domain digital signal is a velocity signal.

15. A method for converting vibration-related signals acquired by a machine vibration monitoring system, the method comprising:
(a) receiving a time-domain analog signal that is indicative of a vibration level of a machine;
(b) converting the time-domain analog signal into a first time-domain digital signal;
(c) storing the first time-domain digital signal in a data storage device;
(d) accessing the first time-domain digital signal from the data storage device;
(e) performing a mathematical operation on the first time-domain digital signal to generate a second time-domain digital signal, wherein the second time-domain digital signal is indicative of the vibration level of the machine, and wherein the mathematical operation is selected from the group consisting of an integration operation and a differentiation operation.

16. The method of claim 15 wherein step (e) comprises generating a plurality of output data values of the second time-domain digital signal according to:
yₙ=A·xₙ+B·xₙ₋₂+C·yₙ₋₁+D·yₙ₋₂,
where
yₙ is an nth output data value of the second time-domain digital signal,
yₙ₋₁ is an output data value of the second time-domain digital signal prior to yₙ,
yₙ₋₂ is an output data value of the second time-domain digital signal prior to yₙ₋₁,
xₙ is an nth input data value of the first time-domain digital signal,
xₙ₋₁ is an input data value of the first time-domain digital signal prior to xₙ,
xₙ₋₂ is an input data value of the first time-domain digital signal prior to xₙ₋₁, and A, B, C and D are constants.

17. The method of claim 15 wherein the mathematical operation is an integration operation, the first time-domain digital signal is an acceleration signal, and the second time-domain digital signal is a velocity signal.

18. The method of claim 15 wherein the mathematical operation is an integration operation, the first time-domain digital signal is a velocity signal, and the second time-domain digital signal is a displacement signal.

19. The method of claim 15 wherein the mathematical operation is a differentiation operation, the first time-domain digital signal is an velocity signal, and the second time-domain digital signal is an acceleration signal.

20. The method of claim 15 wherein the mathematical operation is a differentiation operation, the first time-domain digital signal is a displacement signal, and the second time-domain digital signal is a velocity signal.
